(19) United States
(12) Patent Application Publication
(10) Pub. No.: US 2007/0182456 A1
(43) Pub. Date: Aug. 9, 2007

(54) Reducing Pin Count When the Digital Output is to be Provided in Differential or Single-ended Form

(75) Inventors: Nitin Agarwal, Bangalore (IN); Eduardo Bartolome, Dallas, TX (US); Sandeep Oswal, Bangalore (IN); Visvesvaraya Pentakota, Bangalore (IN); Jagannathan Venkataraman, Bangalore (IN); Nagarajan Viswanathan, Bangalore (IN); Vinod Paliakara, Bangalore (IN)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/561,424

(22) Filed: Nov. 20, 2006

Related U.S. Application Data
(60) Provisional application No. 60/738,951, filed on Nov. 21, 2005.

(51) Int. Cl. H03K 19/00

(52) U.S. Cl. 326/101

(57) ABSTRACT

An integrated circuit provides digital output signals in either single-ended or differential form on a shared set of pins. A control circuit generates signals to ensure that when one form (single-ended or differential) of outputs are being provided, outputs in the other form are disabled. Outputs in differential form may be provided at twice the frequency as compared to the outputs in single-ended form. As a result the same number of pins can be supported for both single-ended and differential outputs for a desired data throughput, and the pin count of the integrated circuit is reduced.

### RELATED APPLICATIONS

The present application claims priority from co-pending U.S. provisional patent application entitled, “Achieving Reduced Pincount Packages by Combining M-data Rate CMOS Outputs and 2-M Data Rates LVDS outputs”, Ser. No. 60/738,951, filed on Nov. 21, 2005, attorney docket number: TI-61689PS, naming as inventors Agarwal et al, and is incorporated in its entirety herewith.

### BACKGROUND

1. Field

The present disclosure relates generally to the design of integrated circuits, and more specifically to reducing pin count in an integrated circuit when the digital output is to be provided in differential or single-ended form.

2. Related Art

Integrated Circuits (IC) are often required to provide digital outputs in differential or single-ended forms. In a single-ended form, the output signal representing the digital data is provided on a single signal pin referenced to a ground pin. On the other hand, in a differential form, the output signal representing the digital data is provided across a pair of signal pins without reference to a ground pin or other reference terminal.

The pins noted above are provided in a package and used for interfacing with external devices or components, and may thus be referred to as package pins.

There is a general need to reduce the number of pins when providing such features at least because the reduced pin count leads to advantages such as smaller packages and low cost.

### BRIEF DESCRIPTION OF THE DRAWINGS

The present invention will be described with reference to the following accompanying drawings, which are described briefly below.

FIG. 1 is a block diagram illustrating the details of an embodiment of the present invention.

FIG. 2A is a block diagram illustrating the internal details of a portion of an output buffer block in an embodiment of the present invention.

FIG. 2B is a block diagram illustrating the internal details of a portion of an output buffer block in another embodiment of the present invention.

FIG. 3 is a timing diagram illustrating the relationship between data rates of the CMOS and LVDS outputs in one embodiment.

FIG. 4 is a block diagram of an example system in which various features of the present invention can be implemented.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION

### 1. Overview

According to an aspect of the present invention, an integrated circuit is designed to provide either two single-ended buffered digital outputs each on a respective one of a pair of package pins, or a buffered differential digital output across the pair of package pins. As a result, the total number of pins required in a package of an integrated circuit is reduced.

The integrated circuit may also contain a control circuit which ensures that one form of outputs (single-ended or differential) is disabled when the signal is being provided in the other form on the package pins.

According to another aspect of the present invention, the differential outputs are provided at twice the frequency as compared to the single-ended outputs. Consequently the same number of pins can be supported for both single-ended and differential outputs for the same output data rate (i.e., number of bits sent out in a unit time). In an embodiment, the single-ended outputs are provided according to CMOS logic while differential outputs are provided according to LVDS logic.

Several aspects of the invention are described below with reference to examples for illustration. It should be understood that numerous specific details, relationships, and methods are set forth to provide a full understanding of the invention. One skilled in the relevant art, however, will readily recognize that the invention can be practiced without one or more of the specific details, or with other methods, etc. In other instances, well known structures or operations are not shown in detail to avoid obscuring the features of the invention.

### 2. EXAMPLE EMBODIMENT

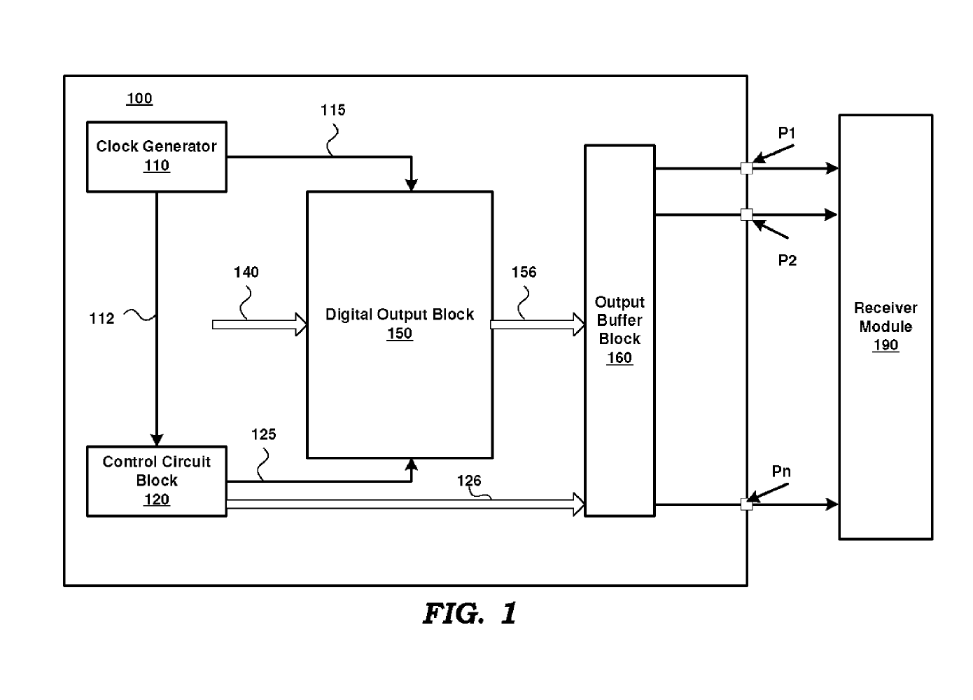

FIG. 1 is a block diagram illustrating the details of an embodiment of the present invention. Integrated circuit (IC) 100 is shown containing digital output block 150, clock generator 110, control circuit block 120, output buffer block 160 and pins P1-Pn. IC 100 may also contain other blocks, which are not shown to avoid obscuring the operational features sought to be illustrated. Receiver module 190 is shown as receiving data outputs of IC 100. Each block/component is described below in further detail.

Data outputs provided by IC 100 on pins P1-Pn may be received by receiver module 190 for further processing. Clock generator 110 provides a clock signal on paths 115 and 112 (can be same clock signals or related by a factor), which control the timing of operation of digital output block 150 and control circuit block 120 respectively. All operations in IC 100 may be synchronized to the clock signal provided by clock generator 110. Control circuit block 120 provides control signals to digital output block 150 (on path 125) and output buffer block 160 (on path 126) for controlling their operations.

Digital output block 150 may receive input signals on path 140 from other processing blocks, process the input signals to generate digital data, and provide the digital data on bus 156. The input signals can be in either analog form or digital form. For example, in case of analog input, digital output block 150 may correspond to a part of a stage/part of an analog to digital converter (ADC). In case of digital input, other digital processing blocks may provide the corresponding input digital data which is processed by digital output block 150 to generate the output digital data on bus 156.

Output buffer block 160 provides adequate drive to data bits received from digital output block 150 on bus 156. The bits are provided on pins P1-Pn (n-count) in either single-ended form (requiring a single pin for each bit) or differential form (requiring two pins for each bit), for example, as specified by a user input. Various aspects of the present invention enable the pin count requirement to be reduced as described below in further detail.

### 3. Multiplexing Single-ended and Differential Outputs on the Same Pins

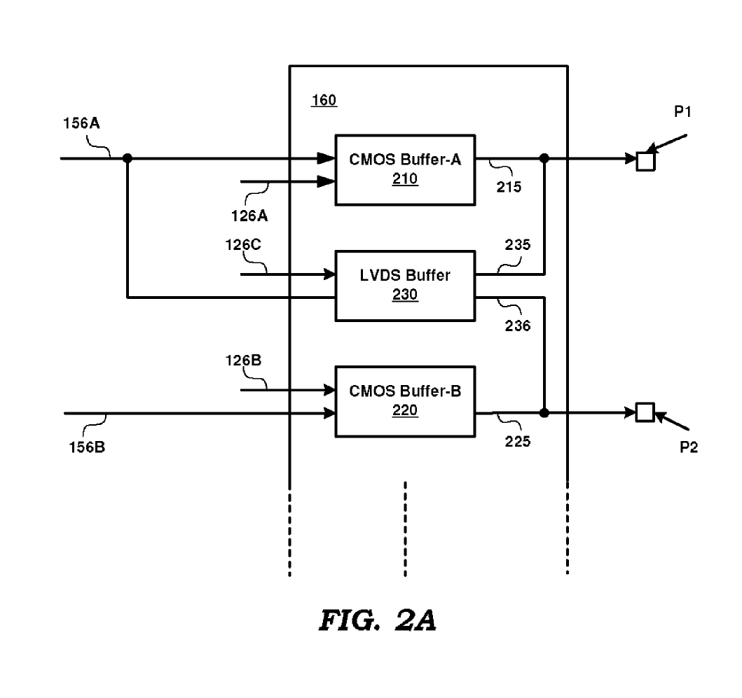

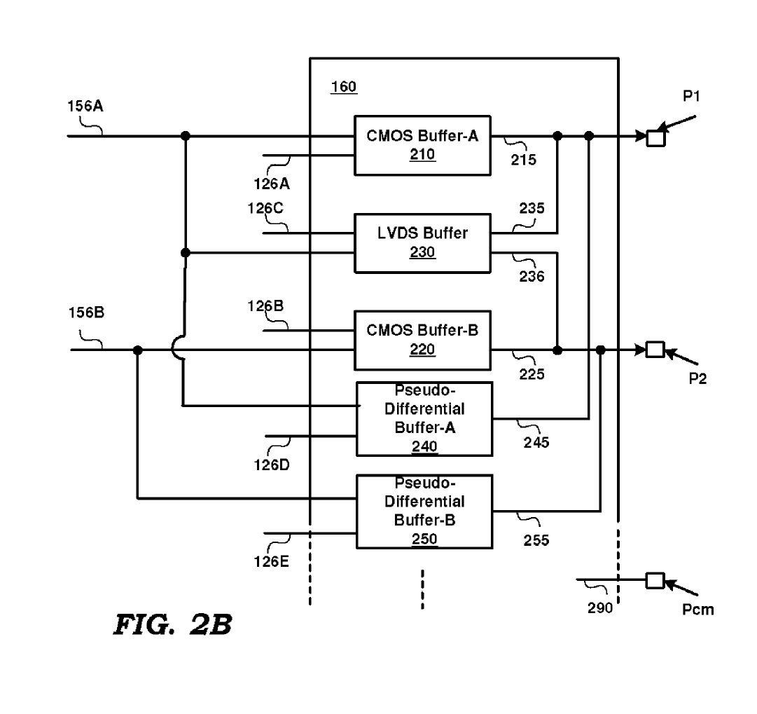

FIG. 2A is a block diagram illustrating the internal details of a portion of output buffer block 160 in an embodiment of the present invention. Output buffer block 160 is shown containing CMOS buffer-A (210), CMOS buffer-B (220) and LVDS buffer (230). As would be readily appreciated by one skilled in the relevant arts, CMOS buffers provide digital data in single-ended form and LVDS buffers provide digital data in differential form. Each buffer is described below in further detail.

CMOS buffer-A(210) and CMOS buffer-B(220) receive one data bit each from digital output block 150 (FIG. 1) on paths 156A and 156B (contained in bus 156) respectively, and provide buffered data outputs at CMOS levels at pins P1 and P2 via paths 215 and 225 respectively. Control signals 126A and 126B (contained in path 126) provided by control circuit block 120 cause CMOS buffer-A (210) and CMOS buffer-B(220) to be tri-stated when LVDS outputs are desired on pins P1/P2.

LVDS buffer (230) receives a data bit on path 156A and provides a buffered and differential data output in LVDS form across pins P1 and P2 via paths 235/236. Control signal 126C causes LVDS buffer(230) to be tri-stated when CMOS outputs are desired on pins P1 and P2. CMOS buffers 210 and 220, and LVDS buffer 230 can be implemented in a known way.

By configuring IC 100 (for example, by programming IC 100, by an external input to IC 100 on a configuration pin, or other techniques) either CMOS or LVDS outputs may be obtained at pins P1-Pn. A user may provide configuration data to control circuit block 120 to specify the desired form of output.

When the configuration data indicates that output data is desired in CMOS form, control circuit block 120 may generate the control signal on path 125 at one logic level (0 or 1) to cause digital output block 160 to provide output data bits on path 156 at a desired frequency M (M being an integer). For example, digital output block 150 (FIG. 1) may provide data on bus 156 on every rising(or falling) edge of the clock signal on path 115.

When the configuration data indicates that output data is desired in LVDS form, control circuit block 120 may generate the control signal on path 125 at the other logic level (1 or 0) to cause digital output block 150 to provide output data bits on bus 156 at twice the frequency 2M. For example, digital output block 150 may provide data (to be output in LVDS form) at both the rising and falling edges of the clock signal on path 115.

Thus, data to be output in LVDS form is provided to output buffer block 160 at twice the frequency as compared to data to be output in CMOS form. The desired frequency M may be specified by another configuration data provided by a user to control circuit block 120, which may in turn control the operation of digital output block 150 to provide output data at the desired frequency using one or more control signals (not shown). Other techniques may also be implemented in IC 100 to achieve the desired frequencies of the CMOS and LVDS output data.

While the description above is provided with respect to single-ended and differential outputs, the features can be extended to provide output bits in pseudo-differential form as well, as described below with respect to FIG. 2B. As is well known in the relevant arts, a shared common mode pin is connected to one of the differential inputs of the receiver device(such as receiver module 190 of FIG. 1) in the pseudo-differential form.

FIG. 2B is a block diagram illustrating internal details of a portion of output buffer block 160 in another embodiment of the present invention. In such an embodiment, output buffer block 160 may provide data outputs in a pseudo-differential form, in addition to the single-ended and differential forms described earlier. In addition to the components described earlier with reference to FIG. 2A, output buffer block 160 is shown containing pseudo-differential buffer-A(240) and pseudo-differential buffer-B (250).

As shown in FIG. 2B, pseudo-differential buffer-A (240) receives a data bit on path 156A, and provides a buffered pseudo-differential output on pin P1 via path 245. Pseudo-differential buffer-B (250) receives a data bit on path 156B, and provides a buffered pseudo-differential output on pin P2 via path 255.

Control signals on paths 126D and 126 E(contained in path 126 of FIG. 1) provided by control circuit block 120 cause pseudo-differential buffers 240 and 250 to be tri-stated (disabled) when single-ended (CMOS) or differential (LVDS) outputs are desired on pins P1/P2. Control signals 126D and 126E enable pseudo-differential buffers 240 and 250 when pseudo-differential outputs are desired on pins P1 and P2.

Generally, when operated to provide pseudo-differential outputs, IC 100 (FIG. 1) may also provide a common-mode voltage on a common-mode reference pin Pcm via path 290 which may be connected to one of two differential inputs of a receiving device (such as receiver module 190 of FIG. 1). The other differential input of the receiving device may be connected to a pseudo-differential output such as may be provided on pins P1-Pn.

As described above with reference to the embodiment of FIG. 2A, output data in differential form is provided at twice the frequency as single-ended data. Consequently, overall data rate when in differential form may be maintained the same as when in single-ended form, even though a smaller number of pins are used. This is briefly illustrated below with a timing diagram.

### 4. Differential Data Clocked at Twice the Frequency as Single-ended Data

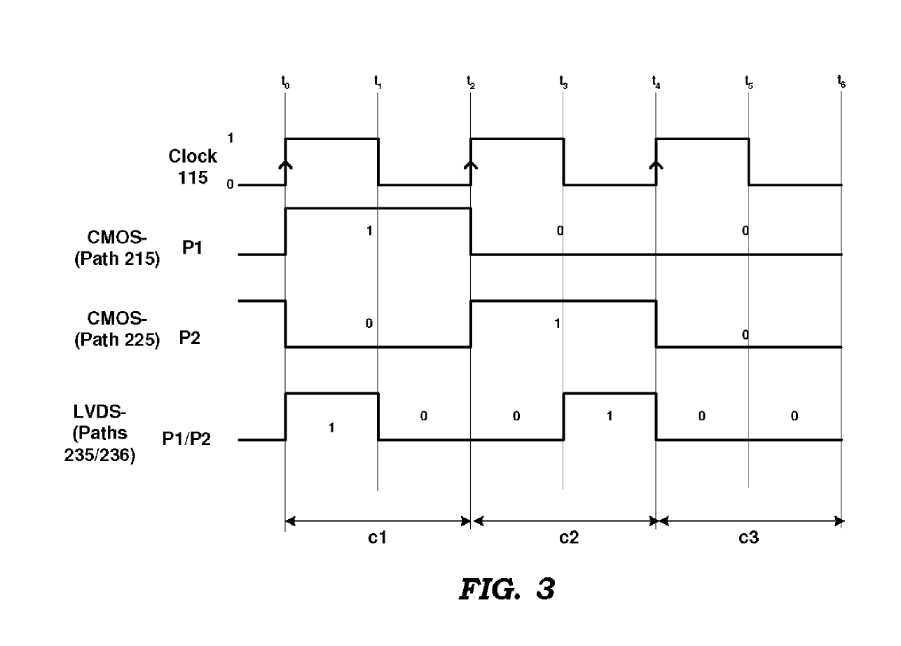

FIG. 3 is an example timing diagram illustrating the relationship between data rates in single-ended form (e.g. CMOS) and differential form (e.g LVDS) in one embodiment. The rising/falling edges of clock 115 are shown as occurring at time instances t1 through t6.

Assuming operation in CMOS mode, bit values of 1, 0, and 0 are shown as being provided on pin P1, and bit values of 0,1 and 0 are shown as being provided on pin P2 in respective consecutive clock cycles c1, c2 and c3. On the other hand, assuming operation in LVDS mode, bit values of 1, 0, 0, 1, 0, and 0 are shown as being provided, with each bit being forwarded in half a clock cycle.

While FIG. 2A depicts the transmission of a set of two single ended outputs and one differential output, the combination of the three blocks (210, 220 and 230) can be replicated for transmission of corresponding number of sets (as represented by the dotted lines). In general, for a data bus width of N (on bus 156), N pins are used to support both of N-bit M-data rate CMOS data and N/2-bit 2M-data rate LVDS data, wherein M represents any integer and N an even number.

Thus, data outputs may be provided in differential, pseudo-differential or single-ended form while reducing IC pin-count. IC 100 designed according to aspects of the present invention may be incorporated in a system as described next with an example.

### 5. EXAMPLE SYSTEM

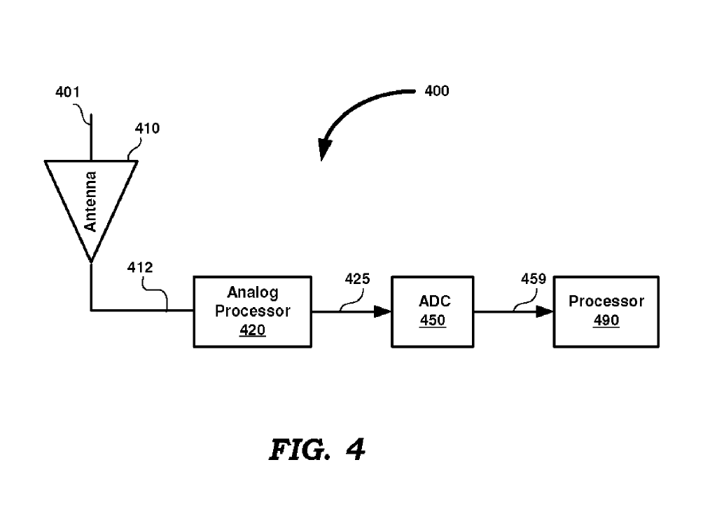

FIG. 4 is a block diagram of an example system incorporating various aspects of the present invention. System 400 is shown containing antenna 410, analog processor 420, analog to digital converter (ADC) 450, and processor (processing unit) 490.

Antenna 410 may receive an analog signal on path 401 and provide an output on path 412 to analog processor 420. Analog processor 420 may perform front-end analog processing operations such as filtering, down conversion etc., on the signal and provide an output to ADC 450 on path 425.

ADC 450 performs analog to digital conversion of the signal received on path 425, and provide digital codes on path 459 to processor 490 for further processing. Antenna 410, analog processor 420 and processor 490 may be implemented using known techniques.

ADC 450 may correspond to IC 100 shown in FIG. 1, and may provide digital data (forming a digital code) on path 459 in single-ended, differential or pseudo-differential form as described above. ADC 450 may be configured to indicate the specific form in which processor 490 is designed to receive digital output, and the digital values provided in the corresponding form as described in the above sections.

### 6. Conclusion

While various embodiments of the present invention have been described above, it should be understood that they have been presented by way of example only, and not limitation. Thus, the breadth and scope of the present invention should not be limited by any of the above described exemplary embodiments, but should be defined only in accordance with the following claims and their equivalents.

What is claimed is:

1. An integrated circuit comprising:
a first pin and a second pin;
a first buffer designed to provide a first digital value in single-ended form on said first pin;
a second buffer designed to provide a second digital value also in single-ended form but on said second pin;
a third buffer designed to provide a third digital value in a differential form across said first pin and said second pin,
wherein said first pin and said second pin are package pins of said integrated circuit.

2. An integrated circuit comprising:
a first pin and a second pin;
a first buffer designed to provide a first sequence of digital values in single-ended form on said first pin;
a second buffer designed to provide a second sequence of digital values also in single-ended form but on said second pin; and
a third buffer designed to provide a third sequence of digital values in a differential form across said first pin and said second pin,
wherein said third buffer provides said third sequence of digital values at a frequency twice that at which said first buffer provides said first sequence of digital values and said second buffer provides said second sequence of digital values,
wherein said first pin and said second pin are package pins of said integrated circuit.

3. The integrated circuit of claim 2, wherein said first buffer is coupled to said first pin by a first path, said second buffer is coupled to said second pin by a second path, said third buffer is coupled to said first pin and said second pin by a third path and a fourth path respectively, said integrated circuit further comprising a control logic designed to generate signals which ensure that said first buffer does not provide digital values on said first path and said second buffer does not provide digital values on said second path when said third buffer provides said third sequence of digital values on said third path and said fourth path in said differential form.

4. The integrated circuit of claim 3, wherein said control logic further ensures that said third buffer does not provide digital values on said third path when said first buffer provides said first sequence of digital value on said first path.

5. The integrated circuit of claim 3, wherein said control logic provides a first control signal to said first buffer when said third buffer provides said third sequence of digital values on said third path and said fourth path in said differential form, wherein said first buffer is tri-stated in response to receiving said first control signal.

6. The integrated circuit of claim 5, wherein said control logic causes each of said first buffer and said second buffer to provide one digital value per a clock period of a clock signal, and said third buffer to provide two digital values in said clock period.

7. The integrated circuit of claim 6, wherein said third buffer provides digital values on a rising edge of said clock signal and also on a falling edge of said clock signal, wherein said first buffer provides digital values on either said falling edge or said rising edge only.

8. The integrated circuit of claim 3, wherein said control logic receives configuration data specifying whether digital values on said first pin and said second pin are to be provided in said single-ended form or said differential form.

9. The integrated circuit of claim 3, wherein said first buffer provides said first sequence of digital values according to Complementary-symmetry Metal Oxide Semi-conductor (CMOS) logic and said third buffer provides said third sequence of digital values according to Low Voltage Differential Signaling (LVDS) logic.

10. The integrated circuit of claim 2, wherein said first buffer, said second buffer and said third buffer are comprised in a buffer block.

11. The integrated circuit of claim 10, wherein said buffer block, said first pin and said second pin are contained in an analog to digital converter (ADC) packaged as a component, whereby said ADC has a reduced pin count.

12. The integrated circuit of claim 3, further comprising:
a common-mode pin provided with a common-mode reference voltage;
a fourth buffer designed to provide a fourth sequence of digital values in a pseudo-differential form on said first pin;
a fifth buffer designed to provide a fifth sequence of digital values also in said pseudo-differential form but on said second pin; and
wherein said fourth buffer is coupled to said first pin by a fifth path, said fifth buffer is coupled to said second pin by a sixth path, said control logic also being designed to generate signals which ensure that said first buffer and said second buffer do not provide digital values on said first path and said second path respectively, and said third buffer does not provide digital values on said third path when said fourth buffer and said fifth buffer provide said fourth sequence of digital values and said fifth sequence of digital values on said fifth path and said sixth path respectively, and
wherein said control logic is also designed to generate signals which ensure that said fourth buffer and said fifth buffer do not provide said fourth sequence of digital values and said fifth sequence of digital values on said fifth path and said sixth path respectively when said first buffer and said second buffer provide digital values on said first path and said second path respectively, or when and said third buffer provides digital values on said third path.

13. A method of providing digital values on pins of an integrated circuit to an external component, said method comprising:
providing a first sequence of digital values on a first pin and a second sequence of digital values on a second pin if said digital values are to be provided to said external component in a singled ended form; and
providing a third sequence of digital values in a differential form across said first pin and said second pin if said digital values are to be provided to said external component in a differential form,
wherein said third sequence of digital values are provided at a frequency twice that at which each of said first sequence of digital values and said second sequence of digital values is provided,
wherein said first pin and said second pin are package pins of said integrated circuit.

14. The method of claim 13, further comprising:
ensuring that said first sequence of digital values is not provided on said first pin, and said second sequence of digital values is not provided on said second pin when said third sequence of digital values is provided across said first pin and said second pin.

15. The method of claim 14, further comprising:
ensuring that said third sequence of digital values is not provided across said first pin and said second pin when said first sequence of digital values is provided on said first pin and said second sequence of digital values is provided on said second pin.

16. The method of claim 13, wherein digital values comprised in each of said first sequence of digital values and said second sequence of digital values are provided once in every clock period of a clock signal, and wherein digital values comprised in said third sequence of digital values are provided twice in every clock period of said clock signal.

17. The method of claim 16, wherein said digital values comprised in said third sequence of digital values are provided on a rising edge of said clock signal and also on a falling edge of said clock signal, wherein said digital values comprised in said first sequence of digital values are provided on either said falling edge or said rising edge only.

18. The method of claim 14, wherein a configuration data specifies whether digital values on said first pin and said second pin are to be provided in said single-ended form or said differential form.

19. The method of claim 14, wherein said first sequence of digital values and said second sequence of digital values are provided in Complementary-symmetry Metal Oxide Semi-conductor (CMOS) logic, and wherein said third sequence of digital values is provided according to Low Voltage Differential Signaling (LVDS) logic.

20. An apparatus for providing digital values on pins to an external component, said apparatus being contained in an integrated circuit, said apparatus comprising:
means for providing a first sequence of digital values on a first pin and a second sequence of digital values on a second pin if said digital values are to be provided to said external component in a singled ended form; and
means for providing a third sequence of digital values in a differential form across said first pin and said second pin if said digital values are to be provided to said external component in a differential form,
wherein said third sequence of digital values are provided at a frequency twice that at which said first sequence of digital values is provided and said second sequence of digital values is provided,
wherein said first pin and said second pin are package pins of an integrated circuit.

21. The apparatus of claim 20, further comprising:
means for ensuring that said first sequence of digital values is not provided on said first pin, and said second sequence of digital values is not provided on said second pin when said third sequence of digital values is provided across said first pin and said second pin.

22. The apparatus of claim 21, further comprising:
means for ensuring that said third sequence of digital values is not provided across said first pin and said second pin when said first sequence of digital values is provided on said first pin and said second sequence of digital values is provided on said second pin.

23. The apparatus of claim 21, further comprising means for specifying whether digital values on said first pin and said second pin are to be provided in said single-ended form or said differential form.

24. A system comprising:
an integrated circuit providing a digital code, said integrated circuit comprising:
a first pin and a second pin, wherein said first pin and said second pin are package pins of said integrated circuit;
a first buffer designed to provide a first sequence of digital values in single-ended form on said first pin;
a second buffer designed to provide a second sequence of digital values also in single-ended form but on said second pin; and
a third buffer designed to provide a third sequence of digital values in a differential form across said first pin and said second pin,
wherein said third buffer provides said third sequence of digital values at a frequency twice that at which said first buffer provides said first sequence of digital values and said second buffer provides said second sequence of digital values,
wherein said digital code is one of said first sequence of digital values, said second sequence of digital values and said third sequence of digital values; and
a processing unit processing said digital code.

25. The system of claim 24, wherein said first buffer is coupled to said first pin by a first path, said second buffer is coupled to said second pin by a second path, said third buffer is coupled to said first pin and said second pin by a third path and a fourth path respectively, said integrated circuit further comprising a control logic designed to generate signals which ensure that said first buffer does not provide said first sequence of digital values on said first path and said second buffer does not provide said second sequence of digital values on said second path, when said third buffer provides said third sequence of digital values on said third path and said fourth path in said differential form.

26. The system of claim 25, wherein said control logic further ensures that said third buffer does not provide said third sequence of digital values on said third path when said first buffer provides said first sequence of digital values on said first path.

27. The system of claim 25, wherein said control logic provides a first control signal to said first buffer when said third buffer provides said third sequence of digital values on said third path and said fourth path in said differential form, wherein said first buffer is tri-stated in response to receiving said first control signal.

28. The system of claim 27, wherein said control logic causes said first buffer and said second buffer to provide one digital value per a clock period of a clock signal, and said third buffer to provide two digital values in said clock period.

29. The system of claim 28, wherein said third buffer provides digital values on a rising edge of said clock signal and also on a falling edge of said clock signal, wherein said first buffer provides digital values on either said falling edge or said rising edge only.

30. The system of claim 25, wherein said control logic receives configuration data specifying whether digital values on said first pin and said second pin are to be provided in said single-ended form or said differential form.

31. The system of claim 24, wherein said integrated circuit comprises an analog to digital converter (ADC) receiving an analog signal and generating said digital code representing a strength of said analog signal at a time instance specified by a clock signal.
